(19) United States
(12) Patent Application Publication
(10) Pub. No.: US 2025/0364992 A1
(43) Pub. Date: Nov. 27, 2025

(54) CONFIGURABLE INTEGRATED CIRCUIT DEVICE

(71) Applicant: Microchip Touch Solutions Limited, Wokingham, Berkshire (GB)

(72) Inventors: James McIntosh, Hutto, TX (US); Atish Ghosh, Austin, TX (US); Richard Petrie, Guildford (GB); Josh Averyt, Chandler, AZ (US)

(73) Assignee: Microchip Touch Solutions Limited, Wokingham, Berkshire (GB)

(21) Appl. No.: 19/217,315

(22) Filed: May 23, 2025

Related U.S. Application Data
(60) Provisional application No. 63/651,349, filed on May 23, 2024.

(51) Int. Cl. H03K 19/0175; G06F 13/42

(52) U.S. Cl. CPC H03K 19/017581; G06F 13/42; G06F 2213/0042

(57) ABSTRACT

Disclosed herein are aspects for configuring a port in an integrated circuit using a configuration state machine. An example aspect begins by determining a current state of internal pull-up and pull-down resistors of the port. The aspect then modifies resistance characteristics of the resistors from the current state. These characteristics indicate a strap configuration of a circuitry connected to the port. The aspect determines a state result based on the strap configuration and the current state. The aspect transitions to a next state based on the state result. The aspect continues by modifying resistance characteristics of the resistors from the next state, indicating a second strap configuration. A second state result is then determined based on the second strap configuration and the next state. The aspect then transitions to a resultant terminal state based on the next state and configures the port to operate in accordance with a port configuration.

### CROSS REFERENCE TO RELATED APPLICATIONS

This application claims priority from U.S. Provisional Application No. 63/651,349, filed on May 23, 2024, which is incorporated herein by reference in its entirety.

### TECHNICAL FIELD

The present disclosure relates to methods and devices for configuring an integrated circuit.

### BACKGROUND

Some integrated circuit devices may be configured, after manufacturing, to set their operation for a given application. If configuration options are limited, for example one of two operating modes need to be selected, a single external pin may be used to select the configuration by either connecting the pin to ground or a supply voltage. However, if the number of possible configurations is higher, configuration selection through pins may be undesirable since additional pins may be needed and this may lead to an increased device size. Thus, a serial interface is often used to configure the device, increasing costs and using additional configuration operations to be performed before the device can be used.

### SUMMARY OF VARIOUS EXAMPLES

In various example aspects present herein, components, systems, methods, and computer-readable mediums can configure a port in an integrated circuit device using a configuration state machine.

In an aspect, an example method for configuring a port in an integrated circuit device using a configuration state machine is described. The method begins by determining a current state of a controllable internal pull-up resistor and a controllable internal pull-down resistor of the port. The method then modifies resistance characteristics of the pull-up resistor and the pull-down resistor from the current state. The resistance characteristics can indicate a strap configuration of a strap circuitry connected to the port. The method continues by determining a state result based on the strap configuration and the current state and transitioning to a next state based on the state result. The method further modifies resistance characteristics of the pull-up resistor and the pull-down resistor from the next state. The resistance characteristics can indicate a second strap configuration. The method can determine a second state result based on the second strap configuration and the next state. From there, the method continues by transitioning to a resultant terminal state based on the next state. The method then concludes by configuring the port, based on the resultant terminal state, to operate in accordance with a port configuration for the resultant terminal state. The resultant terminal state can be one of a plurality of terminal states.

According to various examples, transitioning to the next state of the configuration state machine may comprise implementing a timer having a timer duration and determining the next state based on an evaluation of the state result upon expiration of the timer duration. The timer duration may be based on an RC constant for the port, and the RC constant may be a function of a capacitance of a capacitor. The capacitance of the capacitor may exceed parasitic capacitances of the port. According to various examples, the configuration state machine may comprise a no-strap terminal state associated with a no-resistor strap configuration that permits a pin of the port to float. The configuration state machine may comprise two transition paths for transitioning to the no-strap terminal state. The configuration state machine may have seven terminal states. The controllable internal pull-up resistor and the controllable internal pull-down resistor may be separately controllable to have three respective selectable resistance values. According to various examples, the method may further comprise determining an encoded configuration value for the strap configuration based on the resultant terminal state, and determining the port configuration based on a correlation between the encoded configuration value and the port configuration.

In another aspect, an example configurable integrated circuit device is described. The example device can include a port, a pin operably coupled to the port, and configuration circuitry coupled to the port. The configuration circuitry can comprise a controllable internal pull-up resistor, a controllable internal pull-down resistor, and a capacitor. The configuration circuitry can be configured to implement a configuration state machine that performs operations. The operations can begin by determining a current state of a controllable internal pull-up resistor and a controllable internal pull-down resistor of the port. The operations can then modify resistance characteristics of the pull-up resistor and the pull-down resistor from the current state. The resistance characteristics can indicate a strap configuration of a strap circuitry connected to the port. The operations can continue by determining a state result based on the strap configuration and the current state and transitioning to a next state based on the state result. The operations can further modify resistance characteristics of the pull-up resistor and the pull-down resistor from the next state. The resistance characteristics can indicate a second strap configuration. The operations can determine a second state result based on the second strap configuration and the next state. From there, the operations can continue by transitioning to a resultant terminal state based on the next state. The operations can then conclude by configuring the port, based on the resultant terminal state, to operate in accordance with a port configuration for the resultant terminal state. The resultant terminal state can be one of a plurality of terminal states.

According to various examples, the configuration circuitry may be configured to transition to the next state of the configuration state machine by implementing a timer having a timer duration and determining the next state based on an evaluation of the state result upon expiration of the timer duration. The timer duration may be based on an RC constant for the port, and the RC constant may be a function of the capacitance of the capacitor. The configuration state machine may comprise a no-strap terminal state associated with a no-resistor strap configuration that permits the pin of the port to float. The configuration state machine may comprise two transition paths for transitioning to the no-strap terminal state. The configuration state machine may have seven terminal states. The controllable internal pull-up resistor and the controllable internal pull-down resistor are each separately controllable to have three respective selectable resistance values. Further, according to various examples, the configuration state machine may be implemented in hardware. According to various examples, the configuration state machine may be implemented in firmware. According to various examples, the integrated circuit device may be a microcontroller. According to various examples, the integrated circuit device may be universal serial bus (USB) hub.

In yet another aspect, an example non-transitory computer-readable medium for configuring a port in an integrated circuit device using a configuration state machine is described. The non-transitory computer-readable medium has instructed stored thereon that, when executed by at least one computing device, cause the at least one computing device to perform operations. The operations begin by determining a current state of a controllable internal pull-up resistor and a controllable internal pull-down resistor of the port. The operations can then modify resistance characteristics of the pull-up resistor and the pull-down resistor from the current state. The resistance characteristics can indicate a strap configuration of a strap circuitry connected to the port. The operations can continue by determining a state result based on the strap configuration and the current state and transitioning to a next state based on the state result. The operations can further modify resistance characteristics of the pull-up resistor and the pull-down resistor from the next state. The resistance characteristics can indicate a second strap configuration. The operations can determine a second state result based on the second strap configuration and the next state. From there, the operations can continue by transitioning to a resultant terminal state based on the next state. The operations can then conclude by configuring the port, based on the resultant terminal state, to operate in accordance with a port configuration for the resultant terminal state. The resultant terminal state can be one of a plurality of terminal states.

Further features and advantages, as well as the structure and operation of various aspects, are described in detail below with reference to the accompanying drawings. It is noted that the specific aspects described herein are not intended to be limiting. Such aspects are presented herein for illustrative purposes only. Additional aspects will be apparent to persons skilled in the relevant art(s) based on the teachings contained herein.

### BRIEF DESCRIPTION OF THE SEVERAL VIEWS OF THE DRAWING(S)

The accompanying drawings, which are incorporated herein and form a part of the specification, illustrate aspects of the present disclosure and, together with the description, further serve to explain the principles of the disclosure and to enable a person skilled in the pertinent art to make and use the disclosure.

FIG. 1A shows a block diagram of an I/O port and associated external pin with externally applied pull-up and pull-down resistors, according to various examples.

FIG. 1B shows a block diagram of an I/O port and associated external pin with no externally applied pull-up and pull-down resistors, according to various examples.

FIGS. 2A-2H show block diagrams of a USB hub in various configurations, according to various examples.

FIG. 3 shows a diagram of a configuration state machine for determining an encoded configuration value, according to various examples.

FIG. 4 shows a diagram of circuitry for supporting operation of a timer, according to various examples.

FIG. 5 shows a graph generated based on a simulation of circuitry, according to various examples.

FIG. 6 shows a diagram of circuitry for supporting operation of a capacitor, according to various examples.

FIG. 7 shows a flowchart of a method for configuring a port in an integrated circuit device using a configuration state machine, according to various examples.

In the drawings, like reference numbers generally indicate identical or similar elements. Additionally, generally, the left-most digit(s) of a reference number identifies the drawing in which the reference number first appears.

Various examples will now be described with reference to the accompanying drawings in which some, but not all, examples are shown. Indeed, the examples described and pictured herein should not be construed as being limiting as to the scope, applicability, or configuration of the present disclosure. Rather, these examples are provided so that this disclosure will satisfy applicable legal requirements.

### DETAILED DESCRIPTION

Provided herein are apparatus, device, system, method, computer-readable medium aspects, and combinations and sub-combinations thereof, for configuring a port in an integrated circuit device using a configuration state machine. The following examples describe the aspects in the configuration of a universal serial bus (USB) hub. However, one of ordinary skill in the art would readily appreciate that the examples can be applied in the context of any other integrated circuit devices, in particular, microcontrollers with multi-function pins.

### Port Type Detection

According to various examples, a USB hub may comprise a microcontroller to control the power for each of its downstream ports using, for example, an external port power controller. Three types of such power controllers may be considered, without limitation. One may be a poly fuse, which can be a thermistor. The second may be a port power controller that has an enable pin input and an over-current detect output. The third may be controlled through a serial bus, for example an I2C controlled device that is controlled through I2C messages. One example for such a serial bus is used in “LINX” devices described herein below and uses a device that comprises an I2C physical bus with an extra ALERT pin. Thus, a LINX bus comprises a data I/O line, a clock line, and an alert line. However, this type of communication interface is one example, and various examples may be extended to any I2C device or other serial communication bus whenever a device such as a USB hub comprises serial communication ports. The port type may be programmed into the hub with a programmable setting, or controlled through a strap. According to various examples as described below, the controller type attached to the hub downstream ports may be automatically detected. These principles may be used for other configurable integrated circuit devices.

Automatic detection according to various examples may alleviate programming the device with the type of port device attached to it. This may also alleviate an operation for a user. Such an automatic detection can be used for other configuration purposes.

According to various examples, a USB hub with, for example, four USB ports can comprise the following permutations.
1. One poly fuse per port.
2. One poly fuse per system.
3. One port power controller per downstream port.
4. One to three I²C LINX ports with remaining ports using a ganged poly fuse.
5. One to three I²C LINX ports with remaining ports using a ganged port power switch.
6. Four I²C LINX ports.

Whether a port has battery charging support may be determined by a so-called BC_EN strap. For example, battery charging may not be supported for ports that have poly fuses. Battery charging may be supported by ports that have either a port power switch or an I2C LINX port. The system designer may use a port power controller of the correct size before enabling the port.

### Identifying Port Type

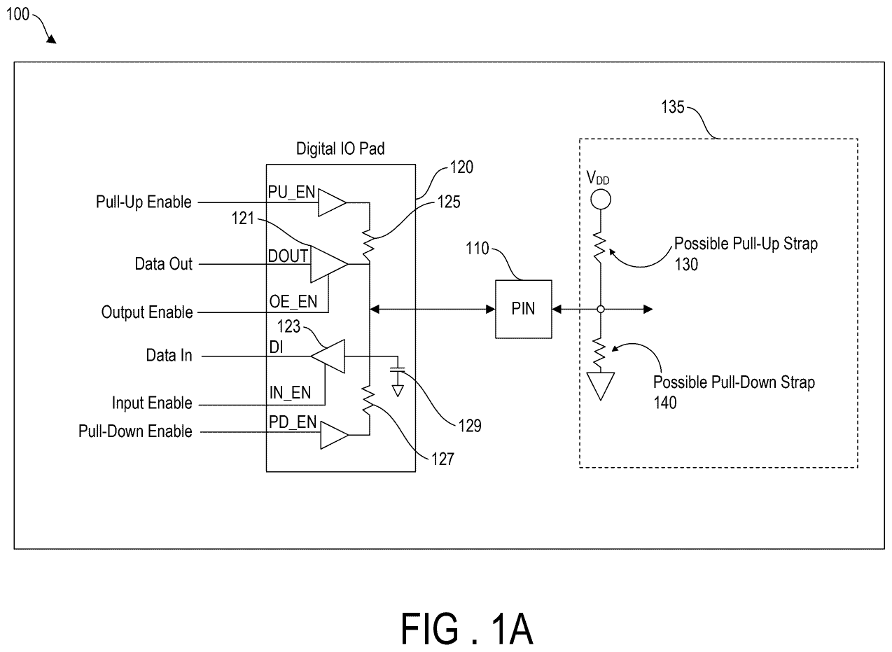

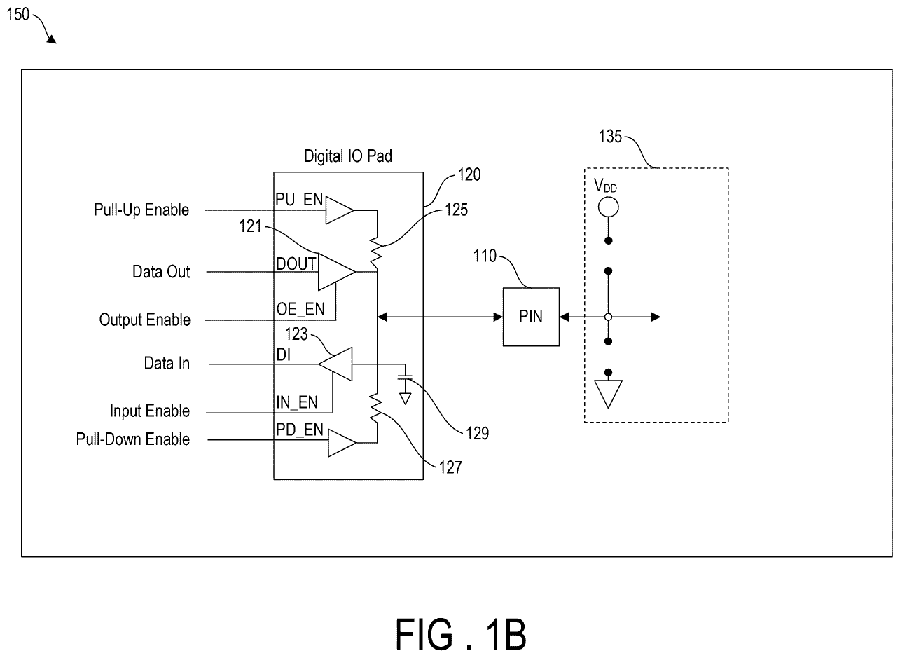

FIG. 1A shows a block diagram 100 of a peripheral input/output (I/O) port 120 and associated external pin 110 with externally applied pull-up 125 and pull-down 127 resistors, according to various examples. Port 120 can be an I/O port of a microcontroller or integrated circuit device and can be organized to be 8-bit or 16-bit wide. However, more or less bits can be provided for an I/O port. The resistor values of the pull-down resistor 127 can vary between 30 KΩ and 80 KΩ over process, voltage, and temperature (PVT) with a nominal 50 KΩ value. The pull-down resistor 127 may operate together with the pull-up resistor 125 and the capacitor 129 to configure the port 120. According to various examples, the pin 110 of the port 120 may be connected to strap circuitry 135, which may function together with an internal pull-up strap resistor 130, an internal pull-down strap resistor 140, and the capacitor 129 to indicate an encoded configuration value that is indicative of a desired configuration for operation of the port 120. As further described herein, such values may be determined through implementation of a configuration state machine having end states for each encoded configuration value.

According to various examples, the strap circuitry 135 may include a pull-up strap resistor 130 and a pull-down strap resistor 140, and the effect of the strap circuitry 135 may be based on the resistance values of the pull-up and pull-down strap resistors 130 and 140, with one of the options for the resistance values being an open circuit or an omission of the resistors 130 and 140. As a result, according to various examples, a plurality of encoded configuration values (e.g., seven values) may be implemented for configuring the port 120. A LINX port, as discussed above, may have a 10 KΩ pull-up strap resistor 130 for I2C connected to the pin 110. A poly fuse may have a resistor divider 130/140 connected to the pin 110 to bring a 5 Volt VBUS down to 3.3V levels. The resistor divider used for this port may be a 10 KΩ pull-up strap resistor 130 with a 10 KΩ pull-down strap resistor 140.

If the internal weak pull-down resistor 127 is unable to pull-down the pin 110, then an external pull-up strap resistor 130 may be present that is much stronger than the pull-down resistor 127. If a pull-up is detected, then, for example, an access to the connected device may be performed to distinguish between port configurations that use the same pull-down or pull-up resistor. For example, an access to the LINX device can be performed to distinguish between a poly fuse and a LINX interface.

According to various examples, to identify a configuration, for example in case of a four port USB hub, the four ports may be put into non-combined mode. FIG. 1A shows I/O port 120 having a Data Out driver 121 with an output enable function, and a Data In driver 123 with an input enable function. In addition, a pull-up resistor 125 or a pull-down resistor 127 can be activated to modify resistance values in response to respective control signals.

According to various examples, the pull-down resistor 127 may be applied to an associated port pin 110 using the pull-down enable control signal “Pull-Down Enable” of the corresponding peripheral I/O 120. Then, the pin input of the respective pin 110 may be determined by reading a respective value from the enabled Data In driver 123. By this, it can be identified which pins have pull-ups and which do not.

According to various examples, an external pin of an integrated circuit device may be used for configuring the integrated circuit device. The external pin, for example, may be externally encoded, for example, to one of seven values or states, with the absence of any strap being one of the values or states. The values or states may be determined by external strap conditions, which may be based on the presence, absence, and resistance values of the strap resistors 130 and 140 as shown in FIG. 1A. Again, according to various examples, a no-strap value or state may be detected when, for example no strap resistors 130 or 140 are present. Such a condition may be detectable due to the inclusion of the capacitor 129 in the internal circuitry. According to various examples, the capacitor 129 may be configured between 20 and 5 picofarads (pF), or, in various examples the capacitor 129 may be a 10 pF capacitor.

According to various examples, the resistor options for the strap resistors 140 and 130, respectively, may be, a 200 KΩ pull-down, 200 KΩ pull-up, 10 KΩ pull-down, 10 KΩ pull-up, 102 pull-down, or a 1002 pull-up. Additionally, the strap resistors 140 and 130 may be omitted. FIG. 1B shows a block diagram 150 of an I/O port 120 and associated external pin 110 with no externally applied pull-up and pull-down resistors. According to these various examples, the pin 110 is permitted to float, which may be a detectable state due to the operation of the capacitor 129. The capacitor 129 may be, for example, non-configurable and may therefore have a constant, non-modifiable capacitance of, for example, 10 pF. The internal pull-down resistor 125 and pull-up resistor 127 may have nominal values of, for example, 50Ω. However, other values may apply and the external resistors may have different values. For example, the smallest resistor may, for example, have a nominal value of 10Ω if a respective driver has a driver strength that could not be overridden by a 100Ω resistor according to one example. Other examples may use different values adapted to the respective internal drivers and internal pull-up resistors 125 and pull-down resistors 127.

The value for configuring the port 120 may be determined either via operation of the hardware, or via detection and configuration by firmware. In a hardware implementation, the integrated circuit device may be constructed to implement a configuration state machine that operates to determine a value for configuring the port 120. Alternatively, the state machine may be implemented in the form of firmware code instructions. In either case, the pin 110 may be permitted to float when the strap circuitry 135 omits the resistors 130 and 140 or the resistors 130 and 140 operate as open circuits to V_{DD} or VBUS and ground. In such a floating condition, the voltage at the pin 110 may tend to be pulled unpredictably to a high or low voltage condition. As such, the detection of the value for the pin 110 may be time dependent in an effort to determine the floating condition before the floating condition evolves into a high or low condition that may not be differentiated from a resistor-based voltage divider circuit including non-open circuit resistances for the resistors 130 and 140. Due to the inclusion of the capacitor 129, an RC constant (e.g., a time constant based on resistance and capacitance) of the internal configuration components (i.e., pull-up resistor 125, pull-down resistor 127, and capacitor 129) can be determined and used for establishing a timing threshold for determining the encoded configuration value.

Whether implemented in hardware or firmware, the integrated circuit device may be configured to determine the encoded configuration value for the strap circuitry 135. In various examples, the integrated circuit device may be configured to monitor the input value, and in sequence apply the internal pull-down resistor 127, then the internal pull-up resistor 125, then drive a zero, then drive a one, and finally output a tri-state. According to various examples, at each iterative instance, a timer may be reset, where the duration of the timer is based on the RC constant of the internal configuration components, and the input value may be recorded prior to or upon expiration of the timer. According to various examples, a vector can then be created using the determined input values, which, for example, may result in seven different vectors or encoding values that are, or are correlated to, the encoded configuration values. The vector can then be used since the vector may point to a specific configuration associated with the encoded configuration value of the vector. Table 1 shows an example of reading values for different pull-up or pull-down resistors applied to a pin. The respective resistor values selected for a specific function of the respective pin may be selected such that the value allows for improved performance of that function. The determination of each bit/steps “PULL DOWN”, “PULL UP”, “DRIVE 0”, “DRIVE 1”, and “TRI STATE” may be performed in any order. The vector Hex and Binary values are also provided. Depending on how many different vectors/encoding values are needed, not all of the bits/steps may be required to be used.

TABLE 1

| Strap | Pull | Pull | Drive | Drive | Tri- | Vector | Binary | Encoded |
|---|---|---|---|---|---|---|---|---|
| Component | Down | Up | 0 | 1 | State | Hex | Value | Value |
| 200 KΩ PD | 0 | 1 | 0 | 1 | 0 | 4′h8 | 4′b1000 | Value 1 |
| 200 KΩ PU | 0 | 1 | 0 | 1 | 1 | 4′h9 | 4′b1001 | Value 2 |
| 10 KΩ PD | 0 | 0 | 0 | 1 | 0 | 4′hA | 4′b1010 | Value 3 |
| 10 KΩ PU | 1 | 1 | 0 | 1 | 1 | 4′hB | 4′b1011 | Value 4 |
| 10Ω PD | 0 | 0 | 0 | 0 | 0 | 4′hC | 4′b1100 | Value 5 |
| 10Ω PU | 1 | 1 | 1 | 1 | 1 | 4′hD | 4′b1101 | Value 6 |
| Not Defined | | | | | | 4′hE | 4′b1110 | Invalid |
| No Resistor | 0 | 1 | 0 | 1 | X | 4′hF | 4′b1111 | Value 7 |

Thus, a plurality of different encoded configuration values can be chosen with a single digital port whose functionality may not be influenced or significantly altered by the strap circuitry 135 (e.g., its respective pull-up 130 or pull-down 140 resistors or lack thereof). The respective pull-up or pull down values for the resistors of the strap circuitry 135 can be selected accordingly. A microcontroller as discussed below may have such ports wherein a plurality of such ports are connected with external multi-function pins to be configured according to a desired function, in particular according to a connected device.

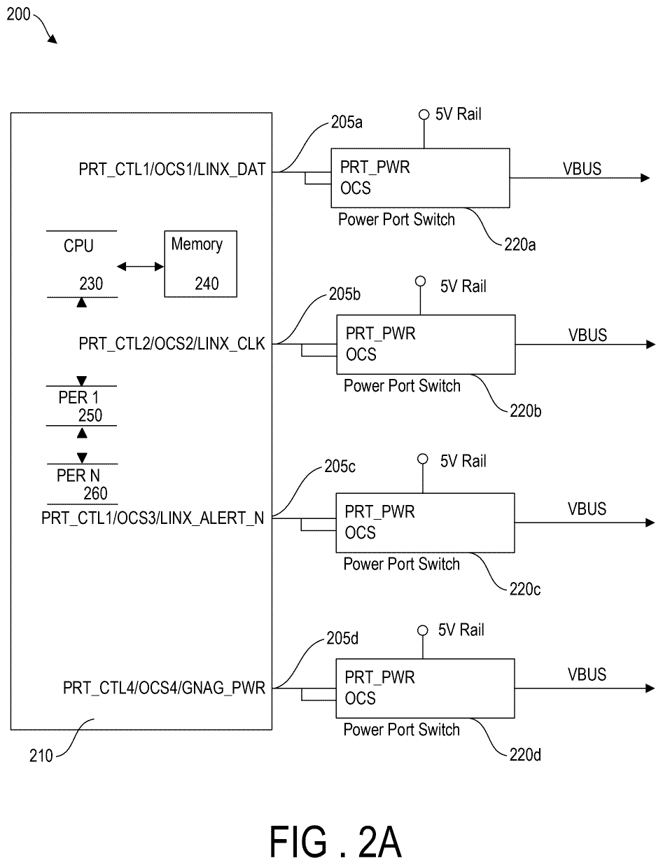

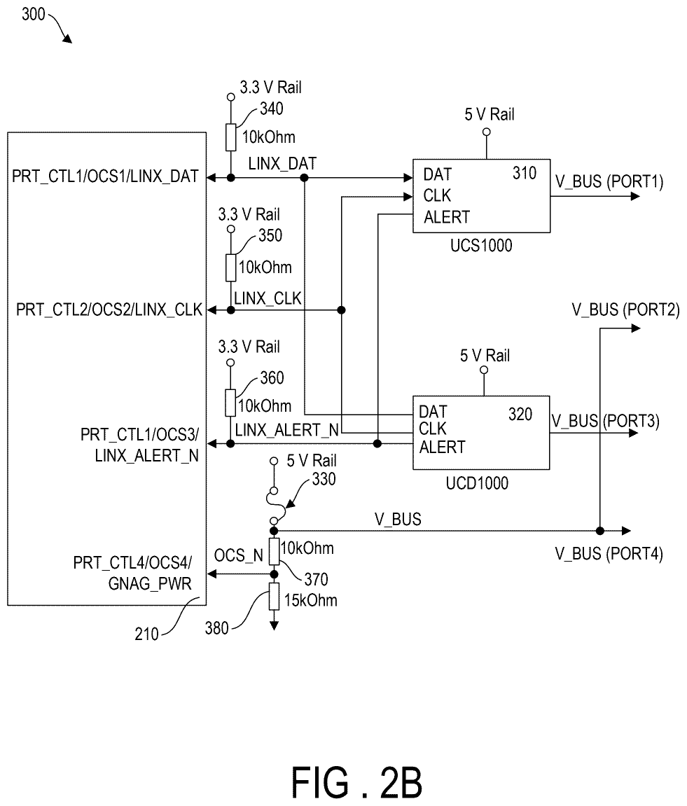

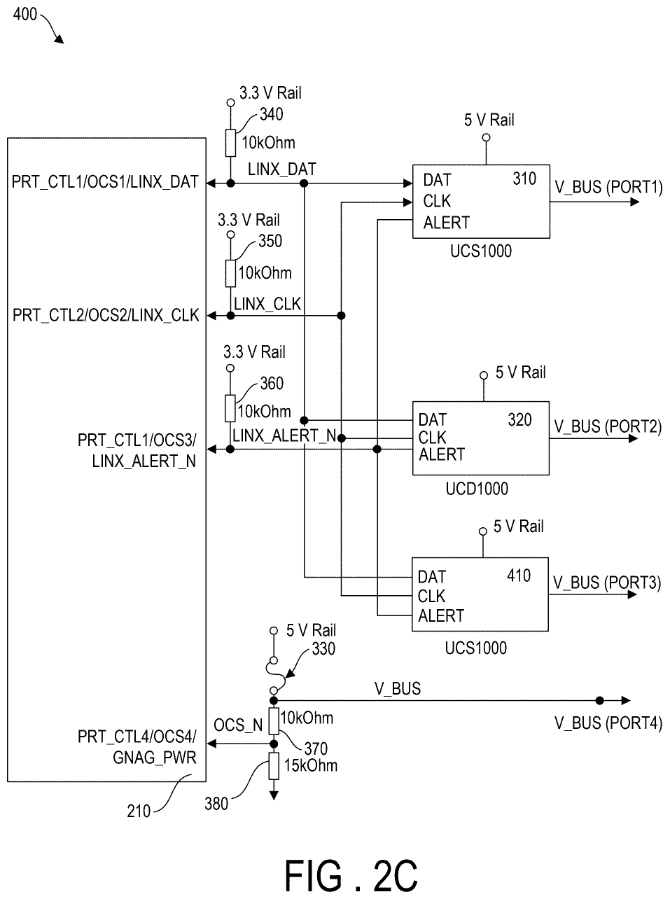

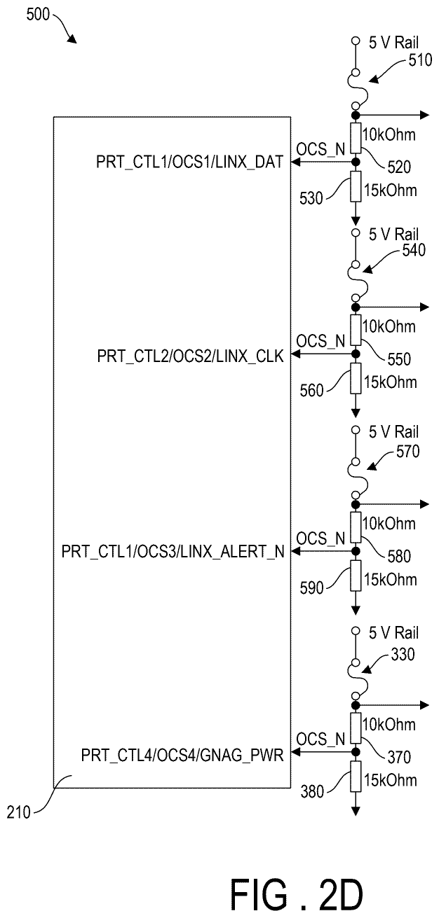

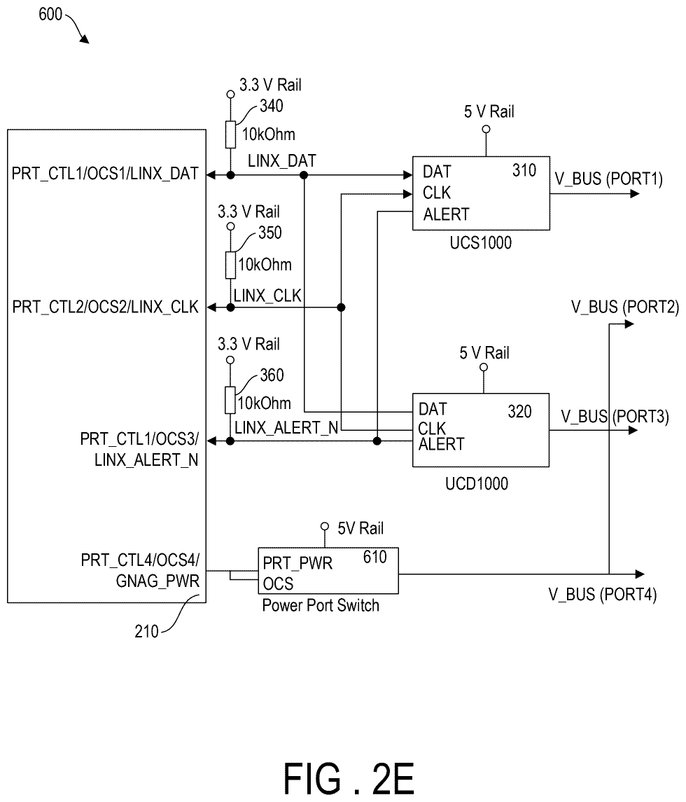

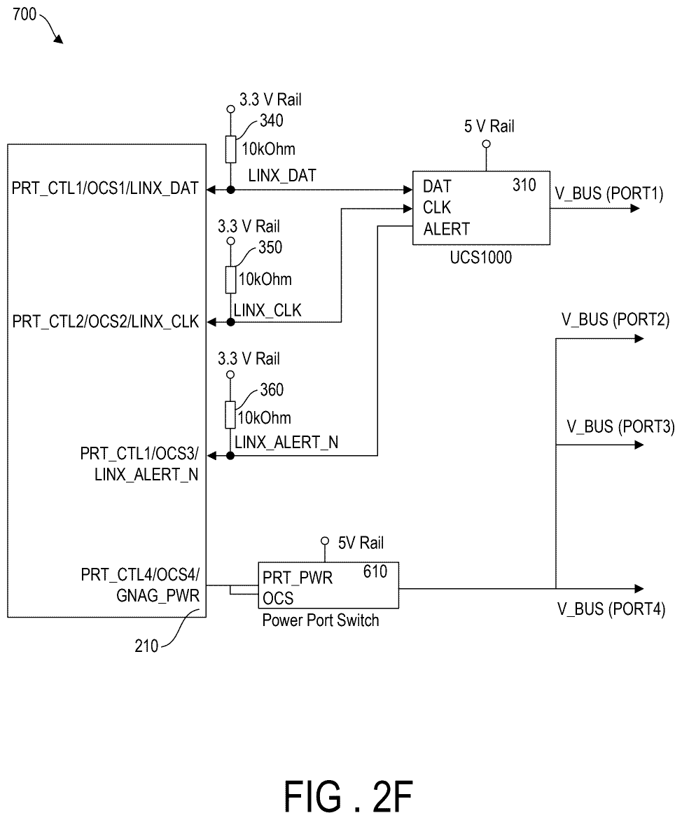

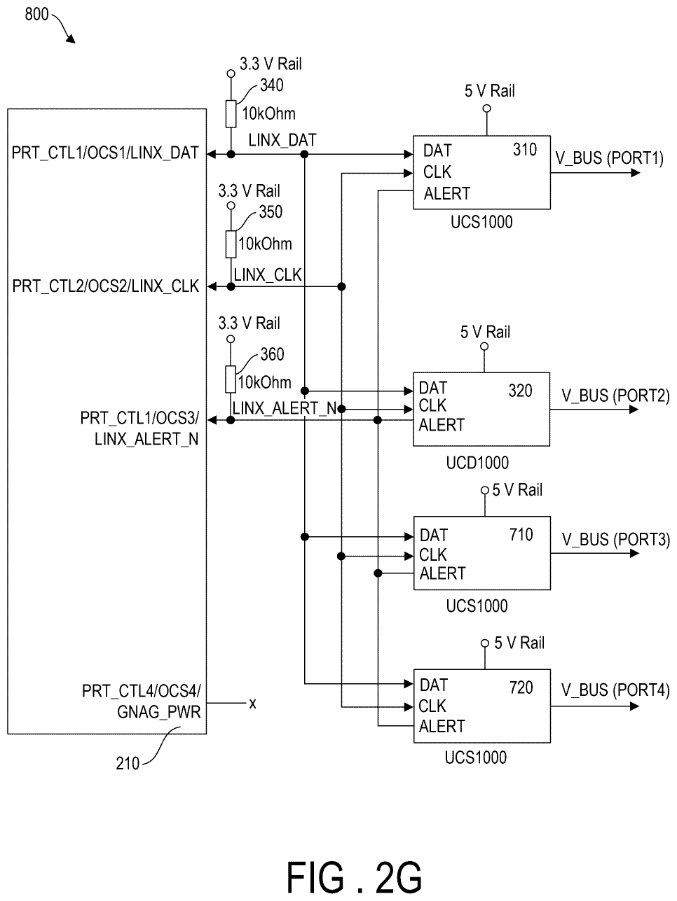

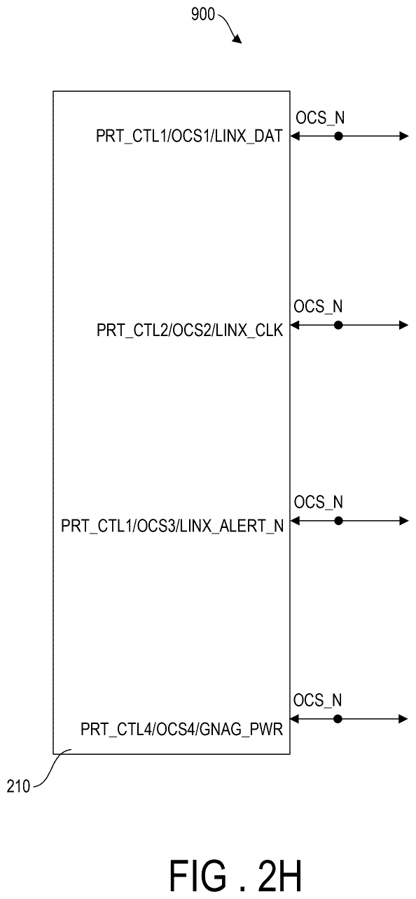

FIGS. 2A-2H show block diagrams of a USB hub controller 210 in various configurations, according to various examples. FIG. 2A shows an example of the USB hub controller 210 comprising a central processing unit (CPU) 230, an associated memory 240, and a plurality of integrated peripheral devices 250-260. USB hub controller 210 can be a microcontroller with a hardware configuration or firmware to be configured of its ports according to various examples described herein. The CPU 230 may be coupled with each of its ports and operable to configure each port using function registers which may use one or more bits to set certain functionality such as enabling pull-up or pull-down functions, data direction, tri-state, connection to other peripheral devices such as serial interfaces, timers, analog-to-digital converters, and the like. The function registers can be, for example, memory-mapped in memory 240 to provide easy access for the CPU 230.

According to various examples, having a pull-up means that the port either has a pull-up resistor connected to a pin (e.g., pin 110), for example, as will be the case for the LINX interface, or it has a pull-up for the poly fuse. According to various examples, a USB hub with four ports, may have three valid combinations. For example, all ports have no connected resistors, all ports have pull-ups, or no port has pull-ups. All other combinations may then, for example, default to a configuration with four poly-fuses.

According to various examples, the ports of the USB hub may be mapped to individual peripheral I/Os of the USB hub controller 210 for the respective USB port. For example, firmware in the USB hub controller 210 may be designed to automatically configure each port according to the various examples described herein. A one-poly-fuse system is not described herein, but based on the description provided, one of ordinary skill in the art would be capable of such an implementation. For systems that use one poly fuse, the poly fuse may be attached to an upstream port. Any over current sense (OCS) event that occurs may reset the whole system, and may be independent of anything the hub does. After an OCS event, the whole hub may go through an enumeration cycle.

### Port Power Switch Only Port Control

If there is no pull-up on any of the ports, then the port has one port power switch per port. In this situation, all the ports are put into combined mode. FIG. 2A shows a port power control system 200 using four power port switches 220a-220d. USB hub controller 210 has four external multi-function pins 205a-205d that are coupled with respective I/O ports (e.g., port 120), as shown in FIG. 1A. The multi-function pins 205a-205d can be one of three functions as indicated in FIG. 2. For example, pin 205a can support a port control function, an over current sense function, or the data line of a LINX interface. Pin 205b can support a port control function, an over current sense function, or the clock line of a LINX interface. Pin 205c can support a port control function, an over current sense function, or the alert in signal function of a LINX interface. Pin 205d can support a port control function, an over current sense function, or a ganged power control function. However, more or less functions may apply according to other examples. In this example, no resistors are connected to the ports to define this configuration.

LINX Port with Poly Fuse

If ports 1, 2, 3 and 4 all have pull-up resistors, there are two possibilities: there is a LINX port on three of the lines and a poly-fuse on the fourth line, or there are four poly fuses. A detection on the LINX interface is performed. If there is a response at address 0x30, 0x31, 0x32, or 0x33, then there is a LINX device present. Port 1 is 0x30, port 2 is 0x31, and port 3 is 0x33. One to four LINX devices may be present. They do not have to be sequential. All ports that do not have LINX devices are put into ganged mode. For example, if ports 2 and 4 do not have LINX devices, then PORT_CFG_SEL_2 and PORT_CFG_SEL_4 both have the GANG_PIN set. COMBINED_MODE is cleared because of the poly fuse.

FIG. 2B shows port power control system 300 using two LINX ports 310 and 320 and poly fuse 330. Resistors 340, 350, and 360 are used to pull up the respective controller ports as shown. Resistor dividers 370 and 380 are used to configure the fourth port as a poly fuse. FIG. 2C shows port power control system 400 using three LINX ports 310, 320, and 410 and one poly Fuse 330. Resistors 340, 350, and 360 are used to pull up the respective controller ports as shown. Resistor dividers 370 and 380 are used to configure the fourth port as a poly fuse.

### Poly Fuse Only Port Power Control

If ports 1, 2, 3 and 4 all have pull-up resistors, and no LINX device was detected, then all the ports have poly fuses as shown in FIG. 2D. FIG. 2D shows port power control system 500 using poly fuses 510, 540, 570, and 330. Each port is connected with a resistor divider 520/530, 550/560, 580/590, and 370/380. The following may be performed:
1. Disable the I2C interface.
2. Set all the ports to non-combined mode. By setting all the ports into non-combined mode, the port power output is ignored, and the pin becomes an OCS.
3. The GANG_PIN is cleared in all registers.

In this configuration all pins are used as over current sense pins.

LINX Port with Port Power Switch

If ports 1, 2, and 3 all have pull-up resistors, and port 4 does not, it means that there is a LINX interface, and the remaining ports use a port power switch. A detection on the LINX interface may be performed. If there is a response at address 0x30, 0x31, 0x32, or 0x33, then there is a LINX device present. Port 1 is 0x30, port 2 is 0x31, and port 3 is 0x33. One to four LINX devices may be present. They do not have to be sequential. All ports that do not have LINX devices are put into ganged mode. For example, if port 1 is the LINX device, then PORT_CFG_SEL_2, PORT_CFG_SEL_3 and PORT_CFG_SEL_4 have the GANG_PIN set. COMBINED_MODE is set because of the presence of a port power switch.

FIG. 2E shows a system 600 with two LINX Ports 310 and 320 and Port power switch 610 as an example of two LINX devices and a port power controller. Resistors 340, 350, and 360 are used to pull up the respective controller ports as shown. FIG. 2F shows a system 700 with one LINX port 310 and one port power switch 610. Resistors 340, 350, and 360 are used to pull up the respective controller ports as shown.

### LINX Only Port Configuration

If a LINX device is attached, then ports 1, 2, and 3 may all have pull-up resistors. If there are four LINX devices attached, then port 4 will not be used. Because it is a full LINX system, the presence of a resistor on port 4 does not affect the functionality of the port. For a full LINX system, the states of the COMBINED_MODE and GANG_PIN for the various registers do not make a difference. Everything may be done through the LINX interface. The firmware may be responsible for turning the ports on and off, and managing OCS events. If there are less than four LINX devices attached, the remaining non-LINX devices may be attached in gang mode using port 4. If there is a resistor on port 4, then the non-LINX devices are assumed to attached with a poly-fuse device, and are used in COMBINED_MODE. If there is no resistor on port 4, then non-LINX devices are assumed to be attached with port power controllers. COMBINED_MODE is used. FIG. 2G shows a system 800 with four LINX ports 310, 320, 710, and 720. Resistors 340, 350, and 360 are used to pull up the respective controller ports as shown.

Additionally, as described herein, FIG. 2H shows a system 900 where no pull-up or pull-down resistors are connected to the pins of the controller 210. However, the absence of the resistors is detectable, according to various examples, as described herein.

The system 900 as provided in FIG. 2H illustrates the implementation of no strap on the pins of the controller 210, which according to various examples can be implemented on select pins as desired for certain configuration for the controller 210. As mentioned above, due to the inclusion of a capacitor (e.g., capacitor 129) a detection time for evaluating the encoded configuration value for a given pin of the controller 210 may be defined based on the RC constant that is a function of the capacitance. The capacitor is able to provide for this detection time and support the implementation of a timer for determining the encoded configuration value (and the associated vector) because the capacitor is larger than, and therefore overwhelms, any parasitic capacitances within the integrated circuit device that may be affecting the pin.

Accordingly, a configuration state machine, as mentioned above, may be implemented by, for example, the USB hub controller 210, to determine the encoded configuration value. Again, according to various examples, the state machine may be implemented in hardware or in firmware. As also described above, the integrated circuit device may perform a sequence of inputs as a procedure to determine the encoded configuration value. The outputs collected as a result of that procedure may define an encoded configuration value for use in configuring the integrated circuit device.

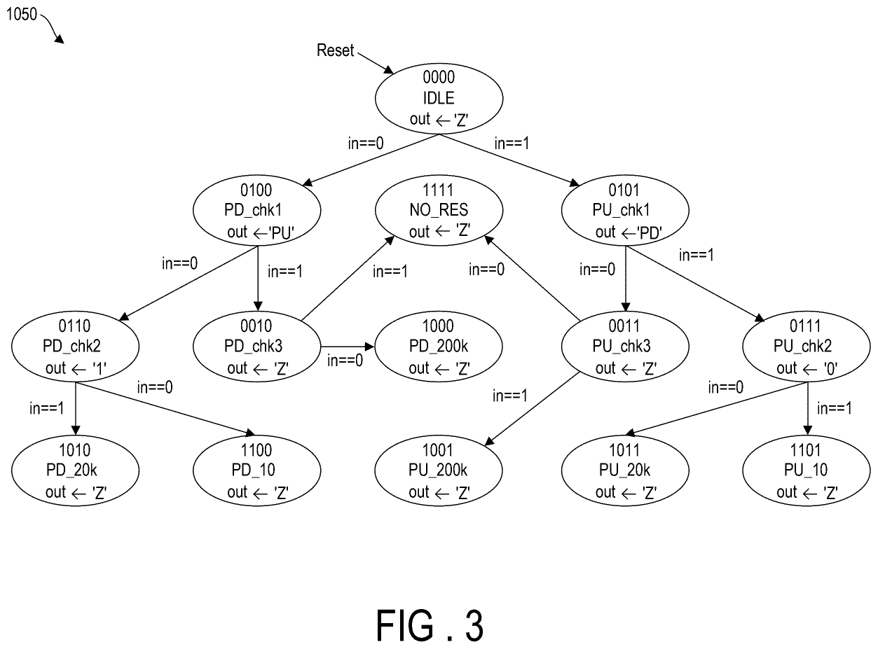

FIG. 3 shows a diagram of a configuration state machine 1050 for evaluating connected strap circuitry to determine an encoded configuration value, according to various examples. In this regard, the state machine includes an initial state 0000, six intermediate (or non-terminal) states 0100, 0101, 0110, 0111, 0010, and 0011, and seven terminal states 1000, 1001, 1010, 1100, 1111, 1011, and 1101. Operation of the state machine 1050 may involve a series of checks, where a test condition is applied and a result is determined for moving to a terminal state that is indicative of the encoded configuration value for the strap circuitry that is connected to the port. As provided in the state machine 1050, and referring back to FIGS. 1A and 1B, at the initial state and at each intermediate state, a check condition may be implemented, which may be one of five conditions. A “Z” condition may be implemented by providing a logical false to Pull-Up Enable and Pull-Down Enable and providing a logical true to Output Enable. A “PU” condition may be implemented by providing a logical false to Pull-Down Enable and providing a logical true to Output Enable and Pull-Up Enable. A “PD” condition may be implemented by providing a logical false to Pull-Up Enable and providing a logical true to Output Enable and Pull-Down Enable. A “0” condition may be implemented by providing a logical false at Data Out, and a logical true at Pull-Up Enable, Pull-Down Enable, and Output Enable. A “1” condition may be implemented by providing a logical true at Data Out, and a logical true at Pull-Up Enable, Pull-Down Enable, and Output Enable.

Moreover, movement to an intermediate state of the state machine 1050 may involve the implementation of a timer as described herein, with expiration of the timer duration (e.g., TIMER_DONE) being an exit condition for each intermediate state. In an example of the state machine 1050, a 10Ω internal pull-up or pull-down resistor may not be utilized if the mode pin is also used as an output. Additionally, in this example state machine, bit 3 indicates that the portion of the procedure involving the pull-up/pull-down check is complete. A non-zero value (or a logical true), with bit 3 being a logical false, indicates that the pull-up/pull-down check is in progress.

As such, the initial state 0000 may be a starting point due to a reset of the procedure. In this initial state, a Z condition may be implemented and, if Data In is a logical true then the state machine progresses to intermediate state 0101 or if Data In is a logical false then the state machine progresses to intermediate state 0100. At intermediate state 0101, a PD condition may be implemented and, if Data In is a logical true then the state machine progresses to intermediate state 0111 or if Data In is a logical false then the state machine progresses to intermediate state 0011. At intermediate state 0111, a 0 condition may be implemented and, if Data In is a logical true then the state machine progresses to terminal state 1101 and it is determined that the encoded configuration value is the value correlated with strap circuitry being a pull-up 1002 resistor. At intermediate state 0111, a 0 condition may be implemented and, if Data In is a logical false then the state machine progresses to terminal state 1011 and it is determined that the encoded configuration value is the value correlated with strap circuitry being a pull-up 20 KΩ resistor. Further, at intermediate state 0011, a Z condition may be implemented and, if Data In is a logical true then the state machine progresses to terminal state 1001 and it is determined that the encoded configuration value is the value correlated with strap circuitry being a pull-up 200 KΩ resistor. At intermediate state 0011, a Z condition may be implemented and, if Data In is a logical false then the state machine progresses to terminal state 1111 and it is determined that the encoded configuration value is the value correlated with strap circuitry having no resistor.

At intermediate state 0100, a PU condition may be implemented and, if Data In is a logical false then the state machine progresses to intermediate state 0110 or if Data In is a logical true then the state machine progresses to intermediate state 0010. At intermediate state 0110, a 1 condition may be implemented and, if Data In is a logical true then the state machine progresses to terminal state 1010 and it is determined that the encoded configuration value is the value correlated with strap circuitry being a pull-down 20 KΩ resistor. At intermediate state 0110, a 1 condition may be implemented and, if Data In is a logical false then the state machine progresses to terminal state 1100 and it is determined that the encoded configuration value is the value correlated with strap circuitry being a pull-down 1002 resistor. Further, at intermediate state 0010, a Z condition may be implemented and, if Data In is a logical false then the state machine progresses to terminal state 1000 and it is determined that the encoded configuration value is the value correlated with strap circuitry being a pull-down 200 KΩ resistor. At intermediate state 0010, a Z condition may be implemented and, if Data In is a logical true then the state machine progresses to terminal state 1111 and it is determined that the encoded configuration value is the value correlated with strap circuitry having no resistor.

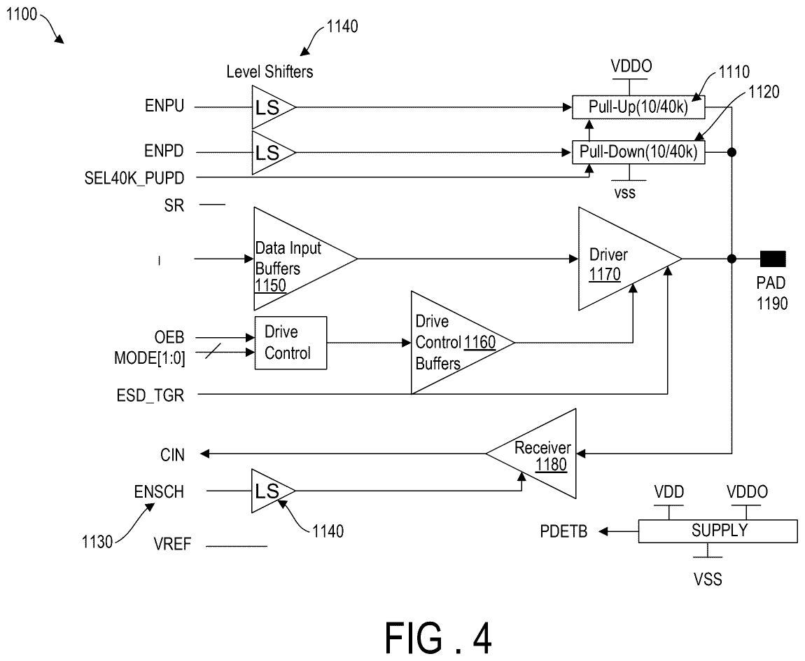

FIG. 4 shows a diagram of circuitry 1100 for supporting the operation of a timer, according to various examples. Circuitry 1100 may be implemented to operate the timer as described herein. Circuitry 1100 can include one or more level shifters (LS) 1140, configured to shift voltage levels between different components of circuitry 1100. LS 1140 can interact with ENPU and ENPD, configured to enable the pull-up resistors and pull-down resistors, respectively.

In this regard, circuitry 1100 may implement two sets of different internal resistors that may have 10 KΩ and 40 KΩ values, internal pull-up 10/40 KΩ resistors 1110 and internal pull-down 10/40 KΩ resistors 1120. To implement multi-bit strapping, the 40 KΩ pull-up 1110 and pull-down 1120 resistors can be used from these sets and their selector line, SEL40K_PUPD, can select the 40 KΩ pull-up 1110 and pull-down 1120 resistors. Additionally, the Schmitt-trigger input ENSCH 1130 may also be enabled. Via simulation of the circuitry 1100, the response graph 1200 can be generated to show the output elements with respect to time.

Circuitry 1100 can include various other components. For example, circuitry 1100 can include data input buffers 1150 configured to receive data inputs, drive control buffers 1160 configured to control the strength of signals being sent throughout circuitry 1100, a driver 1170 configured to drive signals in circuitry 1100 to an external pad 1190, and a receiver 1180 configured to receive incoming signals to circuitry 1100 or its components. Circuitry 1100 can include various other components as would be understood by a person of ordinary skill in the art. Circuitry 1100 components can interact with various other inputs and outputs, such as a power supply pin VDDO, a ground pin VSS, a control signal SR, an output enable buffer signal OEB, an electrostatic discharge trigger ESD_TGR, input capacitance CIN, and other signals as would be understood by a person of ordinary skill in the art.

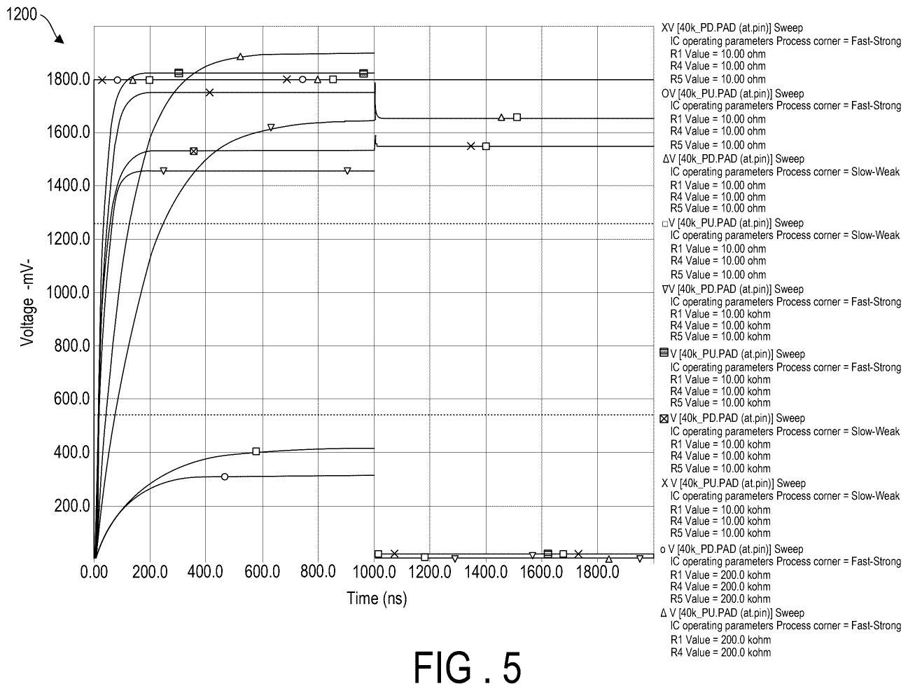

FIG. 5 shows the graph 1200 generated based on a simulation of circuitry 1100, according to various examples. Based on the results shown in graph 1200, according to various examples, the settling time after switching the internal pull-up and pull-down resistors may be about 1000 nanoseconds (ns) for a 200 KΩ external (e.g., strap circuitry) pull-up or pull-down, and about 300 ns for a 10 KΩ external (e.g., strap circuitry) pull-up or pull-down. The simulation times may be lower than an actual time because the simulation does not consider the parasitic capacitances of the integrated circuit device including the package and the pin pads of a printed circuit board. The duration of the timer may be set to double the settling times such that about 2000 ns can be used for a 200 KΩ external (e.g., strap circuitry) pull-up or pull-down and about 600 ns can be used for a 10 KΩ external (e.g., strap circuitry) pull-up or pull-down. Additionally, according to various examples, an OTP bit may be provided to change the timing configuration, for example, for the 200 KΩ Pull-Up/Pull-Down between 1, 2, 4, and 8 μs, with corresponding values for 10 KΩ Pull-up/Pull-down for 0.3, 0.6, 1.2, and 2.4 μs. Moreover, according to various examples, the default timings may be 2 us for 200 KΩ Pull-Up/Pull-Down, with a corresponding value of 0.6 μs for 10 KΩ Pull-Up/Pull-Down resistors.

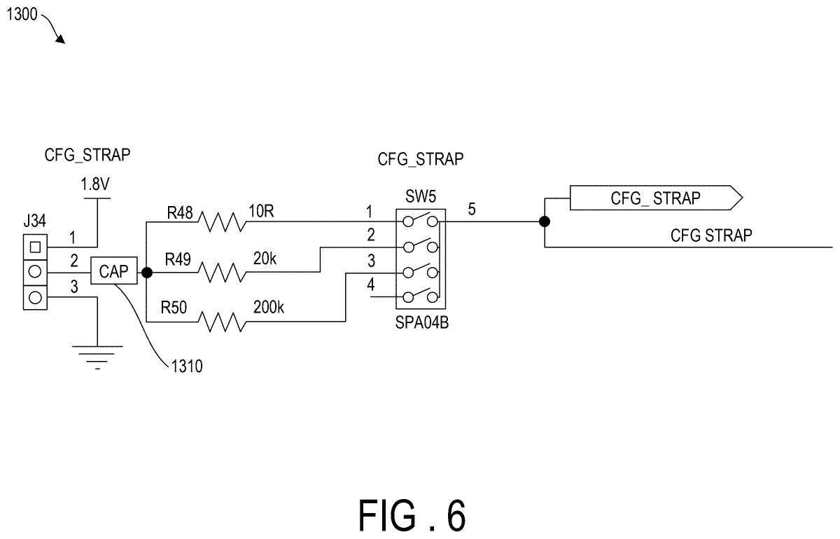

FIG. 6 shows a diagram of circuitry 1300 for supporting the operation of a capacitor 1310, according to various examples. Capacitor 1310 may be implemented in the same manner as capacitor 129. Capacitor 1310 can be configured to provide 10 pF capacitance. Circuitry 1300 can include, for example, 10Ω (e.g., R48), 20 KΩ (e.g., R49), and 200 KΩ (e.g., R50) resistors. Capacitor 1310 can allow for the resistors (e.g., 10Ω, 20 KΩ, and 200 KΩ) to be selectable for insertion into circuitry 1300. Each of the resistors can be coupled to either Pull-Up or Pull-Down via capacitor 1310. Circuitry 1300 can include a connector J34 with various pins. The various pins can be connected to a power supply, a ground, capacitor 1310, and any other component as would be understood by a person of ordinary skill in the art. The resistors (e.g., 10Ω, 20 KΩ, and 200 KΩ) can feed into a switch with various terminals. A strap configuration output, such as CFG_STRAP, can follow from the switch. In a configuration of circuitry 1300 involving a 10 pF capacitor 1310, capacitor 1310 can be configured to ensure that a detection timing, particularly for a “No Strap” case, is deterministic. This can be true because the capacitance of capacitor 1310 can be much larger than any potential parasitic capacitances on the board. Circuitry 1300 can include various other components as would be understood by a person of ordinary skill in the art.

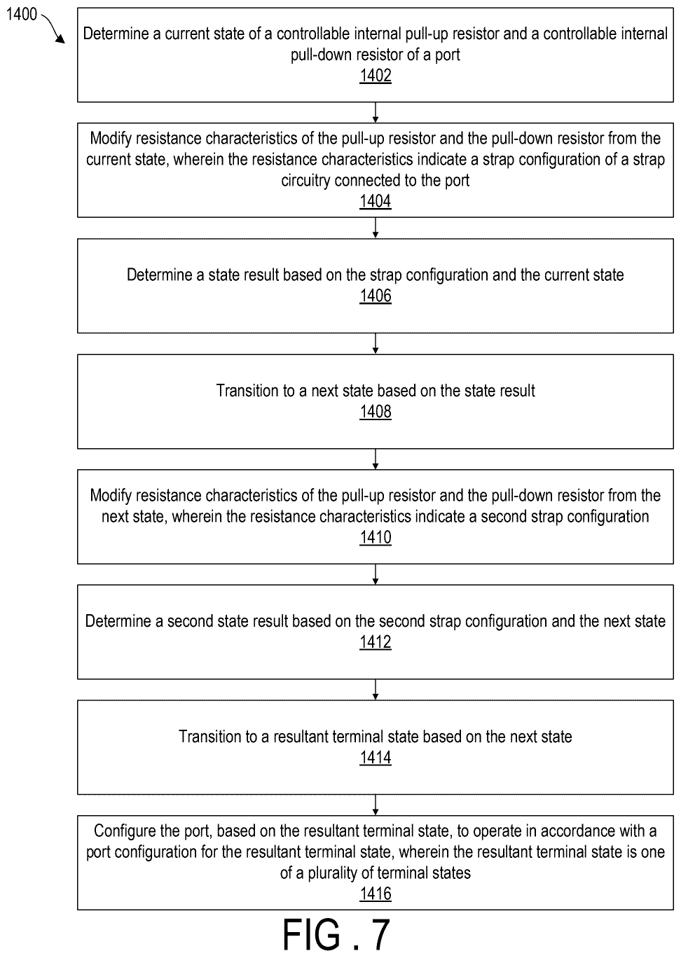

FIG. 7 is a flowchart for a method 1400 for configuring a port in an integrated circuit device using a configuration state machine, according to various examples. It is to be appreciated that more or fewer operations than those shown in FIG. 7 may be performed. Further, some of the steps can be performed simultaneously, or in a different order than shown in FIG. 7, as will be understood by a person of ordinary skill in the art.

Method 1400 can be implemented by configuration state machine 1050. However, method 1400 is not limited to that example aspect.

In operation 1402, a current state of a controllable internal pull-up resistor and a controllable internal pull-down resister of a port is determined.

In operation 1404, resistance characteristics of the pull-up resistor and the pull-down resistor from the current state are modified. The resistance characteristics indicate a strap configuration of a strap circuitry connected to the port. The resistors can be separately controllable such that three respective resistance values are possible.

In operation 1406, a state result based on the strap configuration and the current state is determined.

In operation 1408, transition to a next state occurs based on the state result. This transition can comprise implementing a timer. The timer can have a timer duration. With the timer, the next state can be determined based on an evaluation of the state result upon expiration of the timer duration. The timer duration can be based on an RC constant for the port. The RC constant can be a function of a capacitance of a capacitor. The capacitance of the capacitor can exceed parasitic capacitances of the port.

In operation 1410, resistance characteristics of the pull-up resistor and the pull-down resistor from the next state are modified. The resistance characteristics indicate a second strap configuration. The resistors can be separately controllable such that three respective resistance values are possible.

In operation 1412, a second state result based on the second strap configuration and the next state is determined.

In operation 1414, transition to a resultant terminal state occurs based on the next state. This transition can comprise implementing a timer. The timer can have a timer duration. With the timer, the resultant terminal state can be determined based on an evaluation of the second state result upon expiration of the timer duration. The timer duration can be based on an RC constant for the port. The RC constant can be a function of a capacitance of a capacitor. The capacitance of the capacitor can exceed parasitic capacitances of the port.

In operation 1416, the port is configured, based on the resultant terminal state, to operate in accordance with a port configuration for the resultant terminal state. The resultant terminal state can be one of a plurality of terminal states. An encoded configuration value can be determined for the second strap configuration based on the resultant terminal state. In this way, the port configuration can be based on a correlation between the encoded configuration value and the port configuration.

The configuration state machine can comprise a no-strap terminal state associated with a no-resistor strap configuration that permits a pin of the port to float. The configuration state machine can comprise two transition paths for transitioning to the no-strap terminal state. The configuration state can comprise seven terminal states.

Based on the teachings contained in this disclosure, it will be apparent to persons skilled in the relevant art(s) how to make and use aspects of this disclosure using data processing devices, computer systems and/or computer architectures. In particular, aspects can operate with software, hardware, and/or operating system implementations other than those described herein.

While this disclosure describes example aspects for exemplary fields and applications, it should be understood that the disclosure is not limited thereto. Other aspects and modifications thereto are possible, and are within the scope and spirit of this disclosure. For example, and without limiting the generality of this paragraph, aspects are not limited to the software, hardware, firmware, and/or entities illustrated in the figures and/or described herein. Further, aspects (whether or not explicitly described herein) have significant utility to fields and applications beyond the examples described herein.

Aspects have been described herein with the aid of functional building blocks illustrating the implementation of specified functions and relationships thereof. The boundaries of these functional building blocks have been arbitrarily defined herein for the convenience of the description. Alternate boundaries can be defined as long as the specified functions and relationships (or equivalents thereof) are appropriately performed. Also, alternative aspects can perform functional blocks, steps, operations, methods, and the like using orderings different than those described herein.

References herein to “one aspect,” “an aspect,” “an example aspect,” or similar phrases, indicate that the aspect described can include a particular feature, structure, or characteristic, but every aspect need not necessarily include the particular feature, structure, or characteristic. Moreover, such phrases are not necessarily referring to the same aspect. Further, when a particular feature, structure, or characteristic is described in connection with an aspect, it would be within the knowledge of persons skilled in the relevant art(s) to incorporate such feature, structure, or characteristic into other aspects whether or not explicitly mentioned or described herein. Additionally, some aspects can be described using the expression “coupled” and “connected” along with their derivatives. These terms are not necessarily intended as synonyms for each other. For example, some aspects can be described using the terms “connected” and/or “coupled” to indicate that two or more elements are in direct physical or electrical contact with each other. The term “coupled,” however, can also mean that two or more elements are not in direct contact with each other, but yet still co-operate or interact with each other.

The breadth and scope of this disclosure should not be limited by any of the above-described exemplary aspects, but should be defined only in accordance with the following claims and their equivalents.

What is claimed is:

1. A method for configuring a port in an integrated circuit device using a configuration state machine, comprising:
determining a current state of a controllable internal pull-up resistor and a controllable internal pull-down resistor of a port;
modifying resistance characteristics of the pull-up resistor and the pull-down resistor from the current state, wherein the resistance characteristics indicate a strap configuration of a strap circuitry connected to the port;
determining a state result based on the strap configuration and the current state;
transitioning to a next state based on the state result;
modifying resistance characteristics of the pull-up resistor and the pull-down resistor from the next state, wherein the resistance characteristics indicate a second strap configuration;
determining a second state result based on the second strap configuration and the next state;
transitioning to a resultant terminal state based on the next state; and
configuring the port, based on the resultant terminal state, to operate in accordance with a port configuration for the resultant terminal state, wherein the resultant terminal state is one of a plurality of terminal states.

2. The method of claim 1, wherein transitioning to a next state comprises implementing a timer having a timer duration and determining the next state based on an evaluation of the state result upon expiration of the timer duration.

3. The method of claim 2, wherein the timer duration is based on an RC constant for the port, wherein the RC constant is a function of a capacitance of a capacitor.

4. The method of claim 3, wherein the capacitance of the capacitor exceeds parasitic capacitances of the port.

5. The method of claim 1, wherein the configuration state machine comprises a no-strap terminal state associated with a no-resistor strap configuration that permits a pin of the port to float.

6. The method of claim 5, wherein the configuration state machine comprises two transition paths for transitioning to the no-strap terminal state.

7. The method of claim 5, wherein the configuration state machine has seven terminal states.

8. The method of claim 1, wherein the controllable internal pull-up resistor and the controllable internal pull-down resistor are separately controllable to have three respective selectable resistance values.

9. The method of claim 1, further comprising:
determining an encoded configuration value for the second strap configuration based on the resultant terminal state; and
determining the port configuration based on a correlation between the encoded configuration value and the port configuration.

10. A configurable integrated circuit device comprising:
a port;
a pin operably coupled to the port; and
configuration circuitry coupled to the port, the configuration circuitry comprising a controllable internal pull-up resistor, a controllable internal pull-down resistor, and a capacitor, wherein the configuration circuitry is to implement a configuration state machine to:
determine a current state of the pull-up resistor and the pull-down resistor;
modify resistance characteristics of the pull-up resistor and the pull-down resistor from the current state, wherein the resistance characteristics indicate a strap configuration;
determine a state result based on the strap configuration and the current state;
transition to a next state based on the state result;
modify resistance characteristics of the pull-up resistor and the pull-down resistor from the next state, wherein the resistance characteristics indicate a second strap configuration;
determine a second state result based on the second strap configuration and the next state;
transition to a resultant terminal state based on the next state; and
configure the port, based on the resultant terminal state, to operate in accordance with a port configuration for the resultant terminal state, wherein the resultant terminal state is one of a plurality of terminal states.

11. The configurable integrated circuit device of claim 10, wherein the configuration circuitry is to transition to the next state by implementing a timer having a timer duration and determining the next state based on an evaluation of the state result upon expiration of the timer duration.

12. The configurable integrated circuit device of claim 11, wherein the timer duration is based on an RC constant for the port, wherein the RC constant is a function of a capacitance of the capacitor.

13. The configurable integrated circuit device of claim 10, wherein the configuration state machine comprises a no-strap terminal state associated with a no-resistor strap configuration that permits the pin to float.

14. The configurable integrated circuit device of claim 13, wherein the configuration state machine comprises two transition paths for transitioning to the no-strap terminal state.

15. The configurable integrated circuit device of claim 13, wherein the configuration state machine has seven terminal states.

16. The configurable integrated circuit device of claim 10, wherein the pull-up resistor and the pull-down resistor are separately controllable to have three respective selectable resistance values.

17. The configurable integrated circuit device of claim 10, wherein the configuration state machine is implemented in hardware.

18. The configurable integrated circuit device of claim 10, wherein the configuration state machine is implemented in firmware.

19. The integrated circuit device of claim 10, wherein the integrated circuit device is a universal serial bus (USB) hub.

20. A non-transitory computer-readable medium having instructions stored thereon that, when executed by at least one computing device, cause the at least one computing device to perform operations comprising:
determining a current state of a controllable internal pull-up resistor and a controllable internal pull-down resistor of a port;
modifying resistance characteristics of the pull-up resistor and the pull-down resistor from the current state, wherein the resistance characteristics indicate a strap configuration of a strap circuitry connected to the port;
determining a state result based on the strap configuration and the current state;
transitioning to a next state based on the state result;
modifying resistance characteristics of the pull-up resistor and the pull-down resistor from the next state, wherein the resistance characteristics indicate a second strap configuration;
determining a second state result based on the second strap configuration and the next state;
transitioning to a resultant terminal state based on the next state; and
configuring the port, based on the resultant terminal state, to operate in accordance with a port configuration for the resultant terminal state, wherein the resultant terminal state is one of a plurality of terminal states.
